(19) United States
(12) Patent Application Publication
(10) Pub. No.: US 2026/0140188 A1
(43) Pub. Date: May 21, 2026

(54) BATTERY CHARACTERISTIC ESTIMATING DEVICE, BATTERY CHARACTERISTIC ESTIMATING METHOD, AND STORAGE MEDIUM

(71) Applicant: HONDA MOTOR CO., LTD., Minato-ku, Tokyo (JP)

(72) Inventor: Takuma Kawahara, Wako-shi (JP)

(21) Appl. No.: 18/685,923

(22) PCT Filed: Sep. 28, 2022
(86) PCT No.: PCT/JP2022/036079

§ 371 Date: Feb. 23, 2024

(30) Foreign Application Priority Data
Sep. 28, 2021 (JP) 2021-157921

(51) Int. Cl. G01R 31/3842; G01R 19/10; G01R 31/367; G01R 31/374

(52) U.S. Cl. CPC G01R 31/3842; G01R 19/10; G01R 31/367; G01R 31/374

(57) ABSTRACT

A battery characteristic estimating device including: an acquisition unit configured to acquire time series data including a current, a voltage, and a temperature of a battery; an open circuit voltage estimating unit configured to estimate an open circuit voltage of the battery; an overvoltage estimating unit configured to estimate an overvoltage from the open circuit voltage of the battery by inputting a desired current and a desired temperature to a learned model that has learned using at least the current and the temperature of the time series data as input data; and a closed circuit voltage estimating unit configured to estimate a closed circuit voltage of the battery by summing the open circuit voltage estimated by the open circuit voltage estimating unit and the overvoltage estimated by the overvoltage estimating unit.

### TECHNICAL FIELD

The present invention relates to a battery characteristic estimating device, a battery characteristic estimating method, and a program. Priority is claimed on Japanese Patent Application No. 2021-157921, filed Sep. 28, 2021, the content of which is incorporated herein by reference.

### BACKGROUND ART

Conventionally, technologies for estimating an output performance and a charging performance of batteries are known. For example, in Patent Document 1, a technology for estimating the internal resistance of a battery on the basis of data of a temperature, a voltage, and a current of the battery, estimating a function representing a relation between an open circuit voltage of the battery and a state of charge of the battery, and calculating a power amount of the battery that can be input and output on the basis of the internal resistance and the function that have been estimated is disclosed.

### CITATION LIST

### Patent Document

### Patent Document 1

Japanese Patent No. 6,383,500

### SUMMARY OF INVENTION

### Technical Problem

Among conventional technologies for estimating an output performance and a charging performance of batteries, there is a technology for estimating a voltage using a learned model acquired by setting the voltage of a battery as a target variable of a machine learning model and performing learning using data of a voltage, a current, a temperature, a state of charge (SOC), and the like as training data. However, in such a conventional technology, a large amount of data needs to be collected for learning of the model, and, in a case in which learning data is insufficient, there are cases in which the learned model outputs an abnormal value, and thus the voltage estimation accuracy deteriorates. As a result, there are cases in which the calculation accuracy of the output performance and the charging performance of the battery deteriorate.

The present invention is in consideration of such situations, and one object thereof is to provide a battery characteristic estimating device, a battery characteristic estimating method, and a program capable of estimating characteristics of a battery with high accuracy using a small amount of data.

### Solution to Problem

A battery characteristic estimating device, a battery characteristic estimating method, and a program according to the present invention employ the following configurations.
(1): According to one aspect of the present invention, there is provided a battery characteristic estimating device including: an acquisition unit configured to acquire time series data including a current, a voltage, and a temperature of a battery; an open circuit voltage estimating unit configured to estimate an open circuit voltage of the battery; an overvoltage estimating unit configured to estimate an overvoltage from the open circuit voltage of the battery by inputting a desired current and a desired temperature to a learned model that has learned using at least the current and the temperature of the time series data as input data; and a closed circuit voltage estimating unit configured to estimate a closed circuit voltage of the battery by summing the open circuit voltage estimated by the open circuit voltage estimating unit and the overvoltage estimated by the overvoltage estimating unit.
(2): In the aspect (1) described above, the open circuit voltage estimating unit estimates the open circuit voltage on the basis of a curve representing a relation between a discharge capacity and the open circuit voltage that is calculated such that error for a voltage that can be regarded as the open circuit voltage out of the time series data is minimized.
(3): In the aspect (1) or (2) described above, the learned model has learned using a difference between the open circuit voltage of a predetermined time estimated by the open circuit voltage estimating unit and a voltage value of the time series data as output data for learning and at least the current and the temperature out of the time series data before the predetermined time as input data for learning.
(4): In the aspect (3) described above, the battery is mounted in a device using electric power, and the overvoltage estimating unit performs learning by collecting the output data for learning and the input data for learning from the device.
(5): In the aspect (4) described above, the overvoltage estimating unit estimates the overvoltage of the device by correcting an output value acquired by inputting a desired current and a desired voltage relating to the battery mounted in the device to the learned model on the basis of a correction value that is unique to the device.
(6): In the aspect (5) described above, the correction value is calculated on the basis of an actually-measured value of the overvoltage of the battery mounted in the device and the overvoltage estimated using the learned model.
(7): According to another aspect of the present invention, there is provided a battery characteristic estimating method using a computer, the battery characteristic estimating method including: acquiring time series data including a current, a voltage, and a temperature of a battery; estimating an open circuit voltage of the battery; estimating an overvoltage from the open circuit voltage of the battery by inputting a desired current and a desired temperature to a learned model that has learned using at least the current and the temperature of the time series data as input data; and estimating a closed circuit voltage of the battery by summing the estimated open circuit voltage and the estimated overvoltage.
(8): According to another aspect of the present invention, there is provided a program causing a computer to: acquire time series data including a current, a voltage, and a temperature of a battery; estimate an open circuit voltage of the battery; estimate an overvoltage from the open circuit voltage of the battery by inputting a desired current and a desired temperature to a learned model that has learned using at least the current and the temperature of the time series data as input data; and estimate a closed circuit voltage of the battery by summing the estimated open circuit voltage and the estimated overvoltage.

### Advantageous Effects of Invention

According to the aspects (1) to (8), battery characteristics can be estimated with high accuracy using a small amount of data. In accordance with this, the battery is effectively utilized, and an adverse effect on the Earth's environment due to disposal thereof can be reduced.

According to the aspect (2), battery characteristics can be estimated by effectively utilizing an OCV curve that is estimated with high accuracy.

According to the aspect (3), an overvoltage can be estimated with high accuracy.

(4) According to the aspect (4), by collecting output data for learning and input data for learning from a practical device, a data collection cost can be reduced, and a learned model having high accuracy can be built.

According to the aspect (5) described above, by correcting an overvoltage estimated by a general learned model on the basis of a correction value that is unique to each device in which the battery is mounted, an overvoltage can be estimated with further higher accuracy.

According to the aspect (6), by utilizing a correction value based on a relation between an actually-measured value and an estimated value, an overvoltage can be estimated using a small amount of data.

### BRIEF DESCRIPTION OF DRAWINGS

FIG. 1 is a diagram illustrating one example of the configuration of a vehicle 10 to which a battery characteristic estimating device 100 according to an embodiment is applied.

FIG. 2 is a diagram illustrating one example of the configuration of the battery characteristic estimating device 100 according to the embodiment.

FIG. 3 is a diagram illustrating one example of a normalized positive-electrode open circuit potential (OCP) curve 160B and a positive-electrode OCP curve 160B# acquired by converting the normalized positive-electrode OCP curve 160B.

FIG. 4 is a diagram illustrating one example of a normalized negative-electrode OCP curve 160C and a negative-electrode OCP curve 160C# acquired by converting the normalized negative-electrode OCP curve 160C.

FIG. 5 is a diagram illustrating one example of an open circuit voltage (OCV) curve 160D derived on the basis of the positive-electrode OCP curve 160B# and the negative-electrode OCP curve 160C#.

FIG. 6 is a diagram illustrating one example of a machine learning model generated by an overvoltage estimating unit 140 according to an embodiment.

FIG. 7 is a diagram illustrating one example of a relation between a target variable and explanatory variables used for generating a machine learning model.

FIG. 8 is a diagram for describing differences between a method of estimating a closed circuit voltage CCV(t) using machine learning of a conventional technology and a method of estimating a closed circuit voltage CCV(t) using machine learning of the present invention.

FIG. 9 is a diagram illustrating one example of an algorithm estimating a power amount Wh for a required power W using a learned model.

FIG. 10 is a diagram illustrating one example of a machine learning model generated by an overvoltage estimating unit 140 according to a modified example.

FIG. 11 is a diagram illustrating one example of a correction value calculated by the overvoltage estimating unit 140.

### DESCRIPTION OF EMBODIMENTS

Hereinafter, a battery characteristic estimating device, a battery characteristic estimating method, and a program according to an embodiment of the present invention will be described with reference to the drawings.

### Configuration of Vehicle

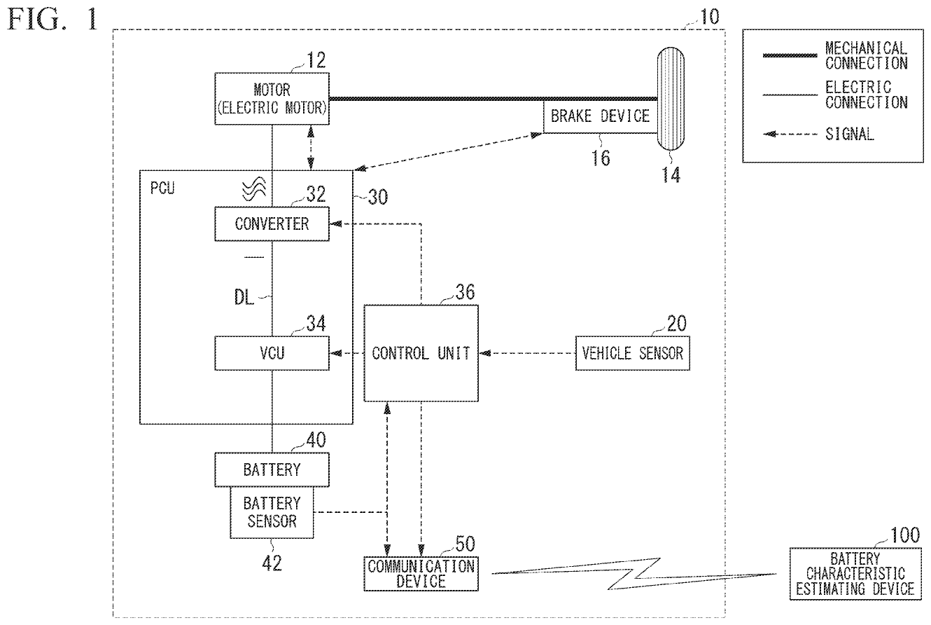

FIG. 1 is a diagram illustrating one example of the configuration of a vehicle 10 to which a battery characteristic estimating device 100 according to an embodiment is applied. The vehicle 10 illustrated in FIG. 1 is a battery electric vehicle (BEV) traveling using an electric motor driven using electric power supplied from a battery (a secondary battery) for traveling. As an alternative, the vehicle 10 may be a plug-in hybrid vehicle (PHV) or a plug-in hybrid electric vehicle (PHEV) in which an external charging function is included in a hybrid vehicle. In addition, the vehicle 10, for example, includes not only a four-wheel vehicle but also an overall mobility traveling using an electric motor driven using electric power supplied from a battery such as a two-wheel vehicle of a saddle-type, a three-wheel vehicle (including, in addition to a vehicle with one front wheel and two rear wheels, a vehicle with two front wheels and one rear wheel), an assistant-type bicycle, or an electric boat.

A motor 12, for example, is a three-phase AC electric motor. A rotor of the motor 12 is connected to drive wheels 14. The motor 12 is driven using electric power supplied from a storage section (not illustrated) included in a battery 40 and delivers rotation power to the drive wheels 14. In addition, the motor 12 generates power using kinetic energy of the vehicle 10 at the time of deceleration of the vehicle 10.

The brake device 16, for example, includes a brake caliper, a cylinder that delivers hydraulic pressure to the brake caliper, and an electric motor that generates hydraulic pressure in the cylinder. The brake device 16 may include a mechanism delivering hydraulic pressure generated in accordance with an operation of a user (driver) of the vehicle 10 on a brake pedal (not illustrated) to the cylinder through a master cylinder as a backup. The brake device 16 is not limited to the configuration described above and may be an electronically-controlled hydraulic brake device that delivers hydraulic pressure of the master cylinder to a cylinder.

A vehicle sensor 20, for example, includes an accelerator degree of opening sensor, a vehicle speed sensor, and a brake pedal pressure sensor. The accelerator degree of opening sensor is mounted in an accelerator pedal, detects an amount of user's operation on the accelerator pedal, and outputs the detected amount of operation to a control unit 36 to be described below as an accelerator degree of opening. The vehicle speed sensor, for example, includes a vehicle wheel speed sensor and a speed calculator that are mounted in each vehicle wheel of the vehicle 10, derives a speed of the vehicle 10 (a vehicle speed) by integrating vehicle wheel speeds detected by the vehicle wheel speed sensors, and outputs the vehicle speed to the control unit 36. The brake pedal pressure sensor is mounted in a brake pedal, detects an amount of driver's operation on the brake pedal, and outputs the detected amount of the operation to the control unit 36 as a brake pedal pressure.

A PCU 30, for example, includes a converter 32 and a voltage control unit (VCU) 34. In FIG. 1, a configuration in which such constituent elements are integrated as the PCU 30 is only one example, and such constituent elements in the vehicle 10 may be arranged to be distributed.

The converter 32, for example, is an AC-DC converter. A DC-side terminal of the converter 32 is connected to a DC link DL. The battery 40 is connected to the DC link DL through the VCU 34. The converter 32 converts an AC generated by the motor 12 into a DC and outputs the DC to the DC link DL.

The VCU 34, for example, is a DC-DC converter. The VCU 34 boosts electric power supplied from the battery 40 and outputs the boosted electric power to the DC link DL.

The control unit 36 controls driving of the motor 12 on the basis of an output from the accelerator degree of opening sensor included in the vehicle sensor 20. In addition, the control unit 36 controls a brake device 16 on the basis of an output from the brake pedal pressure sensor included in the vehicle sensor 20. Furthermore, the control unit 36, for example, calculates a state of charge (SOC; hereinafter also referred to as a “battery charging rate”) of the battery 40 on the basis of an output from a battery sensor 42, which will be described below, connected to the battery 40 and outputs the SOC to the VCU 34. The VCU 34 raises the voltage of the DC link DL in accordance with an instruction from the control unit 36.

The battery 40, for example, is a secondary battery such as a lithium-ion battery that can repeat charging and discharging. A positive electrode active material composing a positive electrode of the battery 40, for example, is a material containing at least one of materials such as nickel cobalt manganese (NCM), nickel cobalt aluminum (NCA), lithium ferrophosphate (LFP), lithium manganese oxide (LMO), and the like, and a negative electrode active material composing a negative electrode of the battery 40, for example, is a material containing at least one of materials such as hard carbon, graphite, and the like. In addition, the battery 40 is mounted to be freely attachable/detachable for the vehicle 10 and, for example, may be a battery pack of a cassette type. The battery 40 stores electric power supplied from an external charger (not illustrated) of the vehicle 10 and performs discharging for traveling of the vehicle 10.

The battery sensor 42 detects physical quantities such as a current, a voltage, a temperature, and the like of the battery 40. The battery sensor 42, for example, includes a current sensor, a voltage sensor, and a temperature sensor. The battery sensor 42 detects a current of a secondary battery composing the battery 40 (hereinafter, simply referred to as “battery 40”) using the current sensor, detects a voltage of the battery 40 using the voltage sensor, and detects a temperature of the battery 40 using the temperature sensor. The battery sensor 42 outputs data of physical quantities such as a current value, a voltage value, a temperature, and the like of the battery 40 which have been detected to the control unit 36 and a communication device 50.

The communication device 50 includes a radio module used for connection to a cellular network and a Wi-Fi network. The communication device 50 may include a radio module for using Bluetooth (registered trademark) and the like. The communication device 50 transmits/receives various kinds of information relating to the vehicle 10, for example, to/from a battery characteristic estimating device 100 using communication of radio modules. The communication device 50 transmits data of physical quantities of the battery 40 output by the control unit 36 or the battery sensor 42 to the battery characteristic estimating device 100. The communication device 50 receives information representing characteristics of the battery 40 that have been diagnosed and transmitted by the battery characteristic estimating device 100 to be described below and may output the received information representing the characteristics of the battery 40 to an HMI (not illustrated) of the vehicle 10.

### Configuration of Battery Characteristic Estimating Device

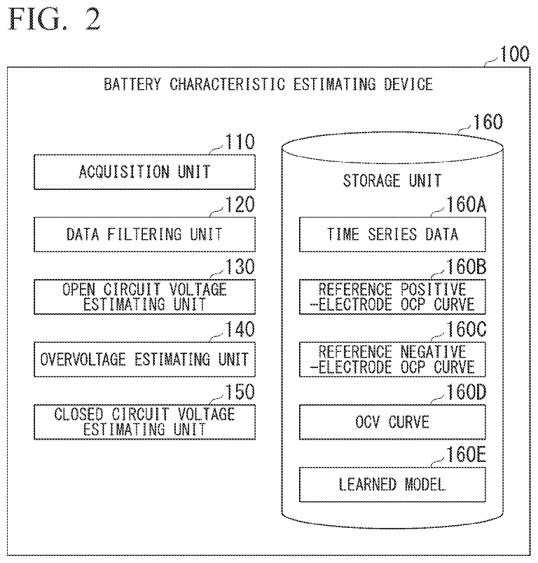

Next, one example of the battery characteristic estimating device 100 that estimates characteristics of the battery 40 of the vehicle 10 will be described. FIG. 2 is a diagram illustrating one example of the configuration of the battery characteristic estimating device 100 according to an embodiment. The battery characteristic estimating device 100, for example, includes an acquisition unit 110, a data filtering unit 120, an open circuit voltage estimating unit 130, an overvoltage estimating unit 140, a closed circuit voltage estimating unit 150, and a storage unit 160. The acquisition unit 110, the data filtering unit 120, the open circuit voltage estimating unit 130, the overvoltage estimating unit 140, and the closed circuit voltage estimating unit 150, for example, are realized by a hardware processor such as central processing unit (CPU) executing a program (software). Some or all of such constituent elements may be realized by hardware (a circuit unit; including circuitry) such as a large scale integration (LSI), an application specific integrated circuit (ASIC), a field-programmable gate array (FPGA), and a graphics processing unit (GPU) or may be realized by software and hardware in cooperation. A program may be stored in advance in a storage device (a storage device including a non-transitory storage medium) such as a hard disk drive (HDD) or a flash memory or may be stored in a storage medium (a non-transitory storage medium) that can be loaded or unloaded such as a DVD or a CD-ROM and be installed by loading the storage medium in a drive device. The storage unit 160, for example, is an HDD, a flash memory, a random access memory (RAM), or the like. The storage unit 160, for example, stores time series data 160A, a normalized positive-electrode OCP curve 160B, a normalized negative-electrode OCP curve 160C, an OCV curve 160D, and a learned model 160E.

The acquisition unit 110 acquires time series data of a current value, a voltage value, a temperature, and the like of the battery 40 from the communication device 50 using a communication interface, which is not illustrated, mounted in the battery characteristic estimating device 100 and stores the acquired time series data in a storage unit 160 as time series data 160A. In addition, the acquisition unit 110 calculates a discharge capacity (amount of discharging) by integrating current values included in the acquired time series data and stores the discharge capacity in the storage unit 160 as time series data 160A. At this time, the acquisition unit 110 may perform a process of excluding data in which a loss or an abnormality has occurred from the acquired time series data. In addition, the discharge capacity may be calculated on the vehicle 10 side and then transmitted to the battery characteristic estimating device 100 through the communication device 50 instead of being calculated by the battery characteristic estimating device 100.

The data filtering unit 120 extracts data in which a voltage change due to charging/discharging is small, in other words, data in which a voltage change is a predetermined value or less from primary acquisition data that has been acquired by the acquisition unit 110 and is stored in the storage unit 160. The voltage change is an amount of change of the voltage at a reference time. The data filtering unit 120 may extract data in which a value of the current is a predetermined value or less out of the extracted time series data, or the data filtering unit 120 may extract data in which a voltage change is a first predetermined value or less, and a value of the current is a second predetermined value or less. In accordance with this, time series data of a voltage and a discharge capacity of the battery 40 at a timing at which the voltage of the battery 40 can be regarded as an OCV can be acquired.

The open circuit voltage estimating unit 130 converts a normalized positive-electrode OCP curve 160B into a positive-electrode OCP curve 160B# representing a change of an open circuit electric potential with respect to a discharge capacity of the positive electrode in accordance with a first parameter group to be described below, converts a normalized negative-electrode OCP curve 160C into a negative-electrode OCP curve 160C# representing a change of an open circuit electric potential with respect to a discharge capacity of the negative electrode in accordance with a second parameter group to be described below, and estimates an OCV curve 160D representing a change of the open circuit voltage with respect to a capacity change of the battery 40 on the basis of a difference between the positive-electrode OCP curve 160B# and the negative-electrode OCP curve 160C# acquired through the conversions. The open circuit voltage estimating unit 130 stores the estimated OCV curve 160D in the storage unit 160.

In addition, the open circuit voltage estimating unit 130 optimizes the OCV curve 160D such that a value of an error function calculated on the basis of the estimated OCV curve 160D and the time series data extracted by the data filtering unit 120 is a threshold or less. The open circuit voltage estimating unit 130 can estimate an open circuit voltage of the battery 40 on the basis of the OCV curve 160D optimized in this way. A specific optimization process of the OCV curve 160D will be described below.

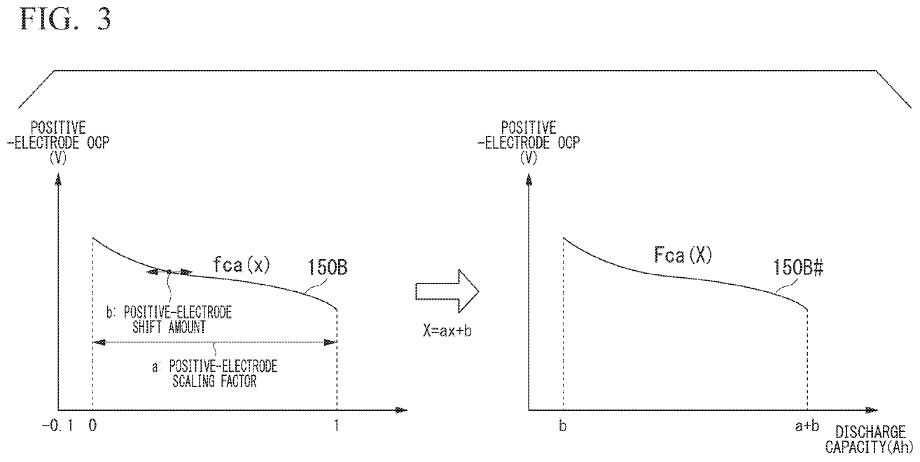

FIG. 3 is a diagram illustrating one example of a normalized positive-electrode OCP curve 160B and a positive-electrode OCP curve 160B#acquired by converting the normalized positive-electrode OCP curve 160B. A left part of FIG. 3 represents the normalized positive-electrode OCP curve 160B, and a right part of FIG. 3 represents the positive-electrode OCP curve 160B# acquired by converting the normalized positive-electrode OCP curve 160B.

As illustrated in the left part of FIG. 3, the normalized positive-electrode OCP curve 160B represents a mathematical model f_{ca}(x) that becomes a reference for deriving the positive-electrode OCP curve 160B# representing a change of the open circuit electric potential with respect to the discharge capacity of the positive electrode, and a width of the discharge capacity x is normalized to 1. The open circuit voltage estimating unit 130 converts the normalized positive-electrode OCP curve 160B into the positive-electrode OCP curve 160B# by using a positive-electrode scaling factor a for converting the normalized width of the discharge capacity of the positive electrode into a width of an actual discharge capacity and a positive-electrode shift amount b that is an amount of shift from the normalized positive-electrode OCP curve 160B to the positive-electrode OCP curve 160B# in a discharge capacity direction.

More specifically, the open circuit voltage estimating unit 130 obtains the mathematical model F_{ca}(X) representing the positive-electrode OCP curve 160B# by converting x that is a variable of no dimension into a variable X having the dimension of the discharge capacity (Ah) using X=ax+b and substituting x=(X−b)/a into f_{ca}(x). In this way, the positive-electrode scaling factor a and the positive-electrode shift amount b represent one example of “first parameter group”.

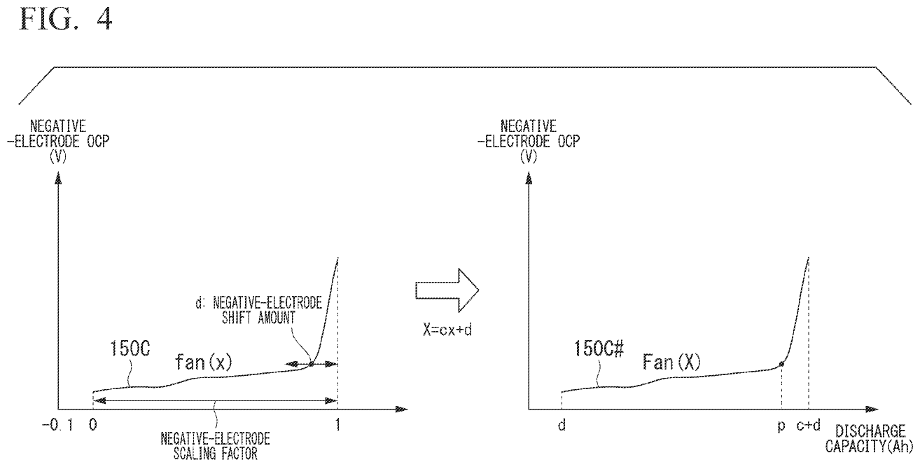

FIG. 4 is a diagram illustrating one example of a normalized negative-electrode OCP curve 160C and a negative-electrode OCP curve 160C# acquired by converting the normalized negative-electrode OCP curve 160C. A left part of FIG. 4 represents the normalized negative-electrode OCP curve 160C, and a right part of FIG. 4 represents the negative-electrode OCP curve 160C# acquired by converting the normalized negative-electrode OCP curve 160C.

As illustrated in the left part of FIG. 4, the normalized negative-electrode OCP curve 160C represents a mathematical model fₐₙ(x) that becomes a reference for deriving the negative-electrode OCP curve 160C# representing a change of the open circuit electric potential with respect to the discharge capacity of the negative electrode, and a width of the discharge capacity x is normalized to 1. The open circuit voltage estimating unit 130 converts the normalized negative-electrode OCP curve 160C into the negative-electrode OCP curve 160C# by using a negative-electrode scaling factor c for converting the normalized width of the discharge capacity of the negative electrode into an actual width of a discharge capacity and a negative-electrode shift amount d that is an amount of shift from the normalized negative-electrode OCP curve 160C to the negative-electrode OCP curve 160C# in a discharge capacity direction.

More specifically, the open circuit voltage estimating unit 130 obtains the mathematical model Fₐₙ(X) representing the negative-electrode OCP curve 160C# by converting x that is a variable of no dimension into a variable X having the dimension of the discharge capacity (Ah) using X=cx+d and substituting x=(X−d)/c into fₐₙ(x). In this way, the negative-electrode scaling factor c and the negative-electrode shift amount d represent one example of “second parameter group”.

In FIGS. 3 and 4, as one example, the normalized positive-electrode OCP curve 160B and the normalized negative-electrode OCP curve 160C have the widths of the discharge capacity x being normalized to 1. However, the present invention is not limited to such a configuration, and more generally, the normalized positive-electrode OCP curve 160B and the normalized negative-electrode OCP curve 160C may be standardized to an arbitrary value as long as there is a mathematical model functioning as a reference for optimizing the first parameter group and the second parameter group.

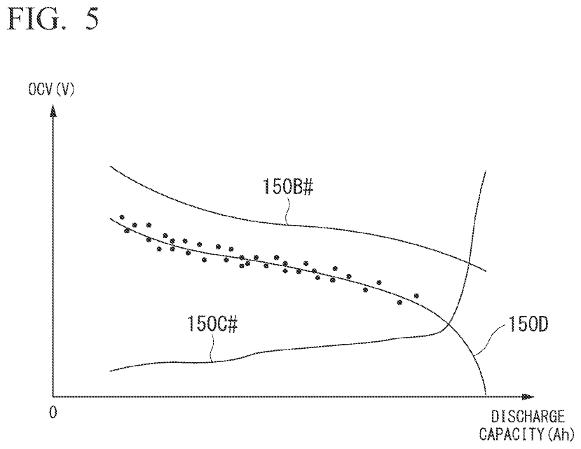

FIG. 5 is a diagram illustrating one example of an OCV curve 160D derived on the basis of the positive-electrode OCP curve 160B# and the negative-electrode OCP curve 160C#. As illustrated in FIG. 5, the open circuit voltage estimating unit 130 estimates the OCV curve 160D by subtracting the negative-electrode OCP curve 160C# acquired in FIG. 4 from the positive-electrode OCP curve 160B# acquired in FIG. 3. Next, the open circuit voltage estimating unit 130 optimizes the first parameter group and the second parameter group such that a value of an error function representing an error between the estimated OCV curve 160D and the time series data extracted by the data filtering unit 120 is a threshold or less.

More specifically, the open circuit voltage estimating unit 130, for example, optimizes the first parameter group and the second parameter group such that the value of the error function is a predetermined value or less, for example, by using a local optimization algorithm such as a BFGS method, a conjugate gradient method, and a COBYLA method or a global optimization algorithm such as a genetic algorithm, a differential evolution method, a SHGO method, or a simulated annealing method. In accordance with this, the open circuit voltage estimating unit 130 can estimate an open circuit voltage OCV(t) of the battery 40 at a predetermined time point t on the basis of the optimized OCV curve 160D.

The overvoltage estimating unit 140 generates a machine learning model (a learned model) by performing machine learning with a difference ΔV(t) (hereinafter, referred to as “overvoltage”) between the open circuit voltage OCV(t) of a predetermined time t estimated by the open circuit voltage estimating unit 130 and a voltage value of the time series data 160A set as a learning output parameter (learning output data) and at least a current and a temperature of the time series data 160A before this predetermined time t set as a learning input parameter (learning input data). By inputting at least a current and a temperature to the generated machine learning model, the overvoltage estimating unit 140 estimates an overvoltage of the battery 40.

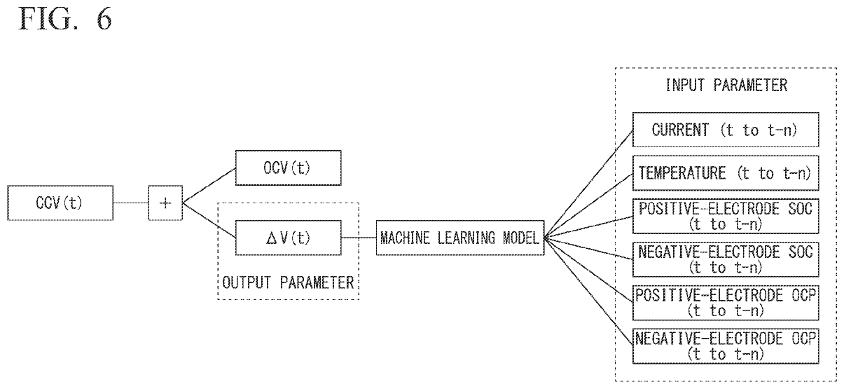

FIG. 6 is a diagram illustrating one example of a machine learning model generated by the overvoltage estimating unit 140 according to the embodiment. As illustrated in FIG. 6, the overvoltage estimating unit 140, for example, generates a machine learning model by performing machine learning with values of the current, the temperature, the positive-electrode SOC, the negative-electrode SOC, the positive-electrode open circuit potential (OCP), a negative-electrode OCP, and the like set as input parameters for the overvoltage ΔV(t) that is an output parameter. The type of machine learning model generated at this time may be an arbitrary model and, for example, may be an algorithm such as a generalized linear model, a decision tree, a neural network, or the like.

In input parameters illustrated in FIG. 6, t represents a predetermined time, and n represents an arbitrary integer. In other words, for example, in FIG. 6, a current (t to t-n) represents a record of current values of the time series data 160A collected from a time point t-n to a time point t. In addition, in FIG. 6, although a current, a temperature, a positive-electrode SOC, a negative-electrode SOC, a positive-electrode OCP, and a negative-electrode OCP are illustrated as input parameters, the present invention is not limited to such a configuration, and, for example, a current, a temperature, a positive-electrode SOC, and a negative-electrode SOC may be set as input parameters. In addition, data input for generating the machine learning model illustrated in FIG. 6 may be acquired from one vehicle 10 or may be acquired from a plurality of vehicles 10. The machine learning model generated in FIG. 6 is for generally estimating an overvoltage of the battery 40 without characteristics of respective batteries 40 being considered.

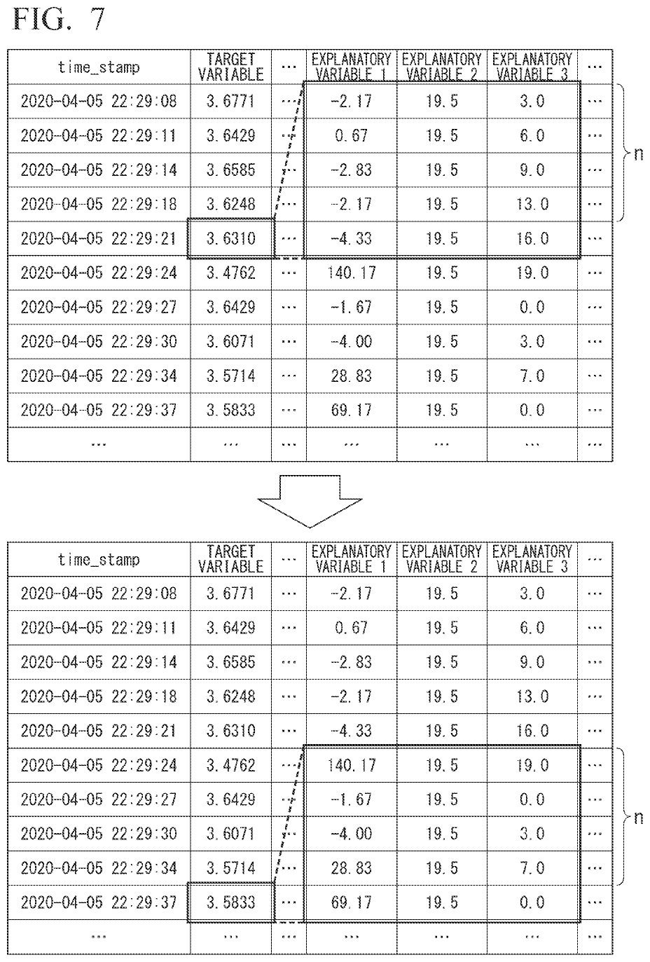

FIG. 7 is a diagram illustrating one example of a relation between a target variable and explanatory variables used for generating a machine learning model. In FIG. 7, a plurality of explanatory variables that are input parameters are associated with the target variable that is an output parameter. By defining a set of the target variable, an explanatory variable of the same time and an explanatory variable of a past time as one record and sequentially shifting a time point that becomes a target for recording a record, the overvoltage estimating unit 140 can generate a plurality of pieces of training data. In addition, in FIG. 7, although n=4 is set, and five records from a record of time-stamp 22:29:08 to a record of time stamp 22:29:21 are acquired, the value of n is not limited to 4, and a supervisor of the battery characteristic estimating device 100 may arbitrarily set the value of n.

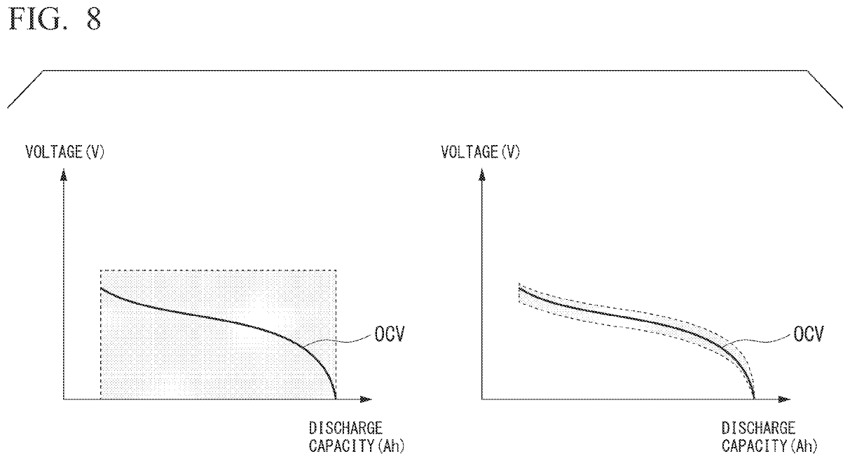

By summing the open circuit voltage OCV(t) estimated by the open circuit voltage estimating unit 130 and the overvoltage ΔV(t) estimated by the overvoltage estimating unit 140, the closed circuit voltage estimating unit 150 estimates a closed circuit voltage CCV(t) of the battery 40. FIG. 8 is a diagram for describing differences between a method of estimating a closed circuit voltage CCV(t) using machine learning of a conventional technology and a method of estimating a closed circuit voltage CCV(t) using machine learning of the present invention. A left part of FIG. 8 illustrates the method of estimating a closed circuit voltage CCV(t) using machine learning of the conventional technology, and a right part of FIG. 8 illustrates the method of estimating a closed circuit voltage CCV(t) using the machine learning of the present invention.

In the machine learning of the conventional technology, the closed-circuit voltage CCV(t) is set as an output parameter, and the closed circuit voltage CCV(t) is directly estimated. For this reason, as illustrated in a dotted-line part of a graph of the left part of FIG. 8, the range of values output using the machine learning is large, and, in order to acquire an output result having high accuracy, a large amount of training data is necessary. On the other hand, in the machine learning of the present invention, only a difference ΔV(t) from the open circuit voltage OCV(t) estimated by the open circuit voltage estimating unit 130 is estimated using the machine learning. For this reason, as illustrated in a dotted-line part of a graph of the right part of FIG. 8, a range of values output using the machine learning is small, and an output result having high accuracy can be acquired without requiring a large amount of training data.

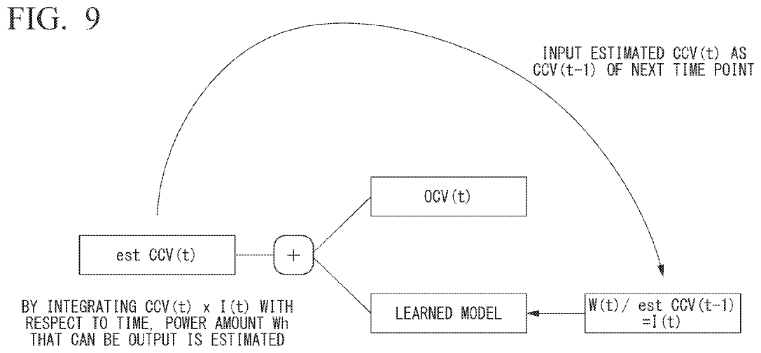

In addition, the closed circuit voltage estimating unit 150 estimates characteristics of the battery 40 in an arbitrary charging/discharging condition on the basis of the estimated closed circuit voltage CCV(t). FIG. 9 is a diagram illustrating one example of an algorithm estimating a power amount Wh for a required power W(t) using a learned model. A supervisor of the battery characteristic estimating device 100, first, determines a required power W(t) for a simulation and defines a current I(t) at a time point t as W(t)/CCV(t−1)=I(t). The closed circuit voltage estimating unit 150 inputs other parameters such as a current I(t), a temperature T(t), and the like set in advance to the overvoltage estimating unit 140 (a learned model), and the overvoltage estimating unit 140 estimates an overvoltage ΔV(t). Next, the closed circuit voltage estimating unit 150 takes a sum of the overvoltage ΔV(t) and the open circuit voltage OCV(t) estimated by the open circuit voltage estimating unit 130 and estimates the closed circuit voltage CCV(t). The estimated closed circuit voltage CCV(t) is fed back as an input parameter for calculating a current value I(t+1)=W(t+1)/CCV(t) at a time point t+1.

By repeating the process described above, for the required power W(t), time series estimation data of the current I(t) the closed circuit voltage CCV(t) can be acquired. The closed circuit voltage estimating unit 150 can estimate a power amount Wh that can be output by integrating CCV(t)×I(t) with respect to time.

According to this embodiment described as above, different from a conventional technology in which a closed circuit voltage CCV(t) is directly estimated using machine learning, the overvoltage estimating unit 140 estimates a difference ΔV(t) between the open circuit voltage OCV(t) estimated by the open circuit voltage estimating unit 130 and the voltage value of the time series data 160A using machine learning, and the closed circuit voltage estimating unit 150 estimates the closed circuit voltage CCV(t) by summing the estimated open circuit voltage OCV(t) and the difference ΔV(t). In accordance with this, characteristics of a battery can be estimated with high accuracy using a small amount of data.

### MODIFIED EXAMPLE

In the embodiment described above, the overvoltage estimating unit 140 of the battery characteristic estimating device 100 generally estimates an overvoltage of the battery 40 without the characteristics of individual batteries 40 being considered. On the other hand, in this modified example, the overvoltage estimating unit 140 further considers the characteristics of respective batteries 40 on the basis of a machine learning model generated in FIG. 6, and thus estimation accuracy of the overvoltage of each battery 40 is improved.

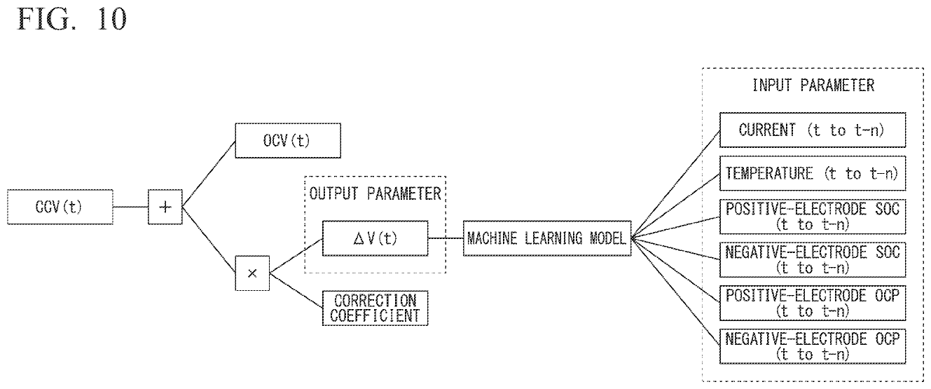

FIG. 10 is a diagram illustrating one example of a machine learning model generated by the overvoltage estimating unit 140 according to the modified example. As illustrated in FIG. 10, the overvoltage estimating unit 140 estimates each overvoltage by correcting an output value acquired by inputting a desired current and a desired temperature of a battery 40 of each vehicle 10 to a machine learning model as input parameters on the basis of a correction value unique to this vehicle 10. Here, the correction value is calculated on the basis of an actually-measured value of the overvoltage of the battery 40 mounted in each vehicle 10 and an overvoltage estimated using the machine learning model. The overvoltage estimating unit 140 calculates a difference between the open circuit voltage estimated by the open circuit voltage estimating unit 130 and the closed circuit voltage of the time series data 160A, thereby calculating an actually-measured value of overvoltage.

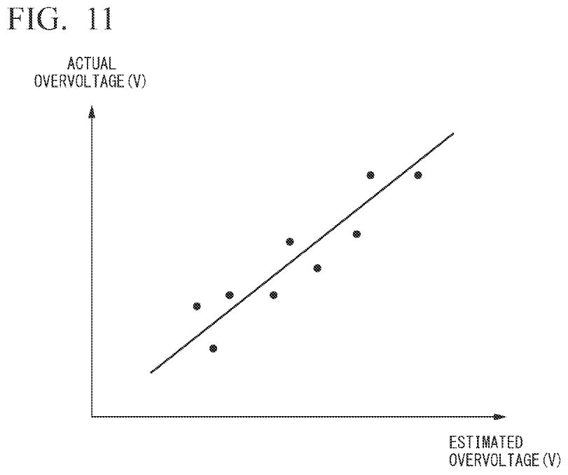

FIG. 11 is a diagram illustrating one example of a correction value calculated by the overvoltage estimating unit 140. As illustrated in FIG. 11, as one example, it can be understood that there is a linear relation between an actual overvoltage and an estimated overvoltage using a technique such as a regression analysis. For this reason, the overvoltage estimating unit 140 sets a coefficient acquired by dividing an actual overvoltage by an estimated overvoltage as a correction value, and thereafter, when input parameters relating to the battery 40 of a corresponding vehicle 10 are input to a machine learning model, the overvoltage estimating unit 140 multiplies an output value of the machine learning model by this correction value. The closed circuit voltage estimating unit 150 sums an overvoltage ΔV(t) corrected though multiplication and the open circuit voltage estimated by the open circuit voltage estimating unit 130, thereby estimating a closed-circuit voltage.

According to this modified example described as above, the battery characteristic estimating device 100 corrects an output value acquired by inputting a desired current and a desired temperature relating to a battery 40 of each vehicle 10 to a machine learning model as input parameters using a correction value unique to this vehicle 10, thereby estimating an overvoltage. In accordance with this, estimation accuracy of an overvoltage of each vehicle 10 can be improved.

The embodiment described above can be represented as below.

A battery characteristic estimating device configured to include a storage device storing a program and a hardware processor and, by executing the program stored in the storage device using the hardware processor, acquire time series data including a current, a voltage, and a temperature of a battery, estimate an open circuit voltage of the battery, estimate an overvoltage from the open circuit voltage of the battery by inputting a desired current and a desired temperature to a learned model that has learned using at least the current and the temperature of the time series data described above as input data, and estimate a closed circuit voltage of the battery by summing the estimated open circuit voltage described above and the estimated overvoltage described above.

As above, although a form for performing the present invention has been described using the embodiment, the present invention is not limited at all to such an embodiment, and various modifications and substitutions can be made within a range not departing from the concept of the present invention.

### REFERENCE SIGNS LIST

10 Vehicle
12 Motor
14 Drive wheel
16 Brake device
20 Vehicle sensor
30 PCU
32 Converter
34 VCU
36 Control unit
40 Battery
42 Battery sensor
50 Communication device
100 Battery characteristic estimating device
110 Acquisition unit
120 Data filtering unit
130 Open circuit voltage estimating unit
140 Overvoltage estimating unit
150 Closed circuit voltage estimating unit
160 Storage unit

What is claim is:

1. A battery characteristic estimating device comprising:
an acquisition unit configured to acquire time series data including a current, a voltage, and a temperature of a battery;
an open circuit voltage estimating unit configured to estimate an open circuit voltage of the battery;
an overvoltage estimating unit configured to estimate an overvoltage from the open circuit voltage of the battery by inputting a desired current and a desired temperature to a learned model that has learned using at least the current and the temperature of the time series data as input data; and
a closed circuit voltage estimating unit configured to estimate a closed circuit voltage of the battery by summing the open circuit voltage estimated by the open circuit voltage estimating unit and the overvoltage estimated by the overvoltage estimating unit.

2. The battery characteristic estimating device according to claim 1, wherein the open circuit voltage estimating unit estimates the open circuit voltage on the basis of a curve representing a relation between a discharge capacity and the open circuit voltage that is calculated such that error for a voltage that can be regarded as the open circuit voltage out of the time series data is minimized.

3. The battery characteristic estimating device according to claim 1, wherein the learned model has learned using a difference between the open circuit voltage of a predetermined time estimated by the open circuit voltage estimating unit and a voltage value of the time series data as output data for learning and at least the current and the temperature out of the time series data before the predetermined time as input data for learning.

4. The battery characteristic estimating device according to claim 3,
wherein the battery is mounted in a device using electric power, and
wherein the overvoltage estimating unit performs learning by collecting the output data for learning and the input data for learning from the device.

5. The battery characteristic estimating device according to claim 4, wherein the overvoltage estimating unit estimates the overvoltage of the device by correcting an output value acquired by inputting a desired current and a desired voltage relating to the battery mounted in the device to the learned model on the basis of a correction value that is unique to the device.

6. The battery characteristic estimating device according to claim 5, wherein the correction value is calculated on the basis of an actually-measured value of the overvoltage of the battery mounted in the device and the overvoltage estimated using the learned model.

7. A battery characteristic estimating method using a computer, the battery characteristic estimating method comprising:
acquiring time series data including a current, a voltage, and a temperature of a battery;
estimating an open circuit voltage of the battery;
estimating an overvoltage from the open circuit voltage of the battery by inputting a desired current and a desired temperature to a learned model that has learned using at least the current and the temperature of the time series data as input data; and
estimating a closed circuit voltage of the battery by summing the estimated open circuit voltage and the estimated overvoltage.

8. A non-transitory computer-readable storage medium having stored thereon a program causing a computer to:
acquire time series data including a current, a voltage, and a temperature of a battery;
estimate an open circuit voltage of the battery;
estimate an overvoltage from the open circuit voltage of the battery by inputting a desired current and a desired temperature to a learned model that has learned using at least the current and the temperature of the time series data as input data; and
estimate a closed circuit voltage of the battery by summing the estimated open circuit voltage and the estimated overvoltage.
